(19) United States
(12) Patent Application Publication
(10) Pub. No.: US 2011/0291105 A1
(43) Pub. Date: Dec. 1, 2011

(54) SEMICONDUCTOR MODULE AND METHOD OF MANUFACTURING THE SAME

(75) Inventors: Kenji HATORI, Tokyo (JP); Shigeru Hasegawa, Tokyo (JP)

(73) Assignee: MITSUBISHI ELECTRIC CORPORATION, Chiyoda-ku (JP)

(21) Appl. No.: 12/971,692

(22) Filed: Dec. 17, 2010

(30) Foreign Application Priority Data
May 31, 2010 (JP) 2010-124138

(51) Int. Cl. H01L 27/12; H01L 21/98

(52) U.S. Cl. 257/77; 438/107; 257/E27.111; 257/E21.705

(57) ABSTRACT

A semiconductor module according to the present invention includes: an insulating substrate (4); a plurality of semiconductor chips (1) disposed on a surface of the insulating substrate (4) so as to be apart from each other; solder layers (9) formed, on a back surface side of the insulating substrate (4), only at positions corresponding to positions at which the respective semiconductor chips (1) are disposed; and a base plate (6) connected to the insulating substrate (4) through the solder layers (9).

### BACKGROUND OF THE INVENTION

1. Field of the Invention

The present invention relates to a semiconductor module and a method of manufacturing the same, and more particularly, to a semiconductor module and a method of manufacturing the same for preventing solder voids generated in a solder layer of a back surface of an insulating substrate on which semiconductor devices are disposed.

2. Description of the Background Art

In a conventional semiconductor module, an insulating substrate on which, for example, power semiconductor chips are mounted is typically soldered to a base plate through a solder layer from the necessities of heat dissipation and fixing of a position.

In this case, when the insulating substrate on which semiconductor chips are mounted is made thinner for reducing the space for the semiconductor module, the influence of warp due to thermal expansion increases in a case where the size of the insulating substrate is increased. This causes a problem of deteriorated assemblability, such as a fear that voids are likely to occur in the solder layer formed below the insulating substrate.

### SUMMARY OF THE INVENTION

An object of the present invention is to provide a semiconductor module capable of preventing the generation of solder voids and keeping excellent assemblability, and a method of manufacturing the same.

A semiconductor module according to the present invention includes: an insulating substrate; a plurality of semiconductor chips disposed on a surface of the insulating substrate so as to be apart from each other; solder layers formed, on a back surface side of the insulating substrate, only at positions corresponding to positions at which the respective semiconductor chips are disposed; and a base plate connected to the insulating substrate through the solder layers.

According to the semiconductor module of the present invention, it is possible to prevent the generation of solder voids and keep excellent assemblability.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows the structure of a semiconductor module according to a first preferred embodiment;

FIG. 2 shows the structure of a semiconductor module according to a second preferred embodiment; and

FIG. 3 shows the structure of a semiconductor module of the basic technology.

### DESCRIPTION OF THE PREFERRED EMBODIMENTS

As shown in FIG. 3, in a semiconductor module of the basic technology of the present invention, semiconductor chips 1 are disposed on metals 3 through solder layers 2, and the plurality of metals 3 are formed apart from each other on an insulating substrate 4.

A metal 5 is formed over an entire back surface of the insulating substrate 4, and the insulating substrate 4 is disposed on a base plate 6 through a solder layer 7.

When the insulating substrate 4 warps due to, for example, thermal expansion as shown in FIG. 3, solder voids 8 occur in the solder layer 7, which deteriorates the assemblability of the semiconductor module.

The present invention described in the following preferred embodiments relates to the structure of a semiconductor module for solving this problem.

### A. First Preferred Embodiment

(A-1. Configuration)

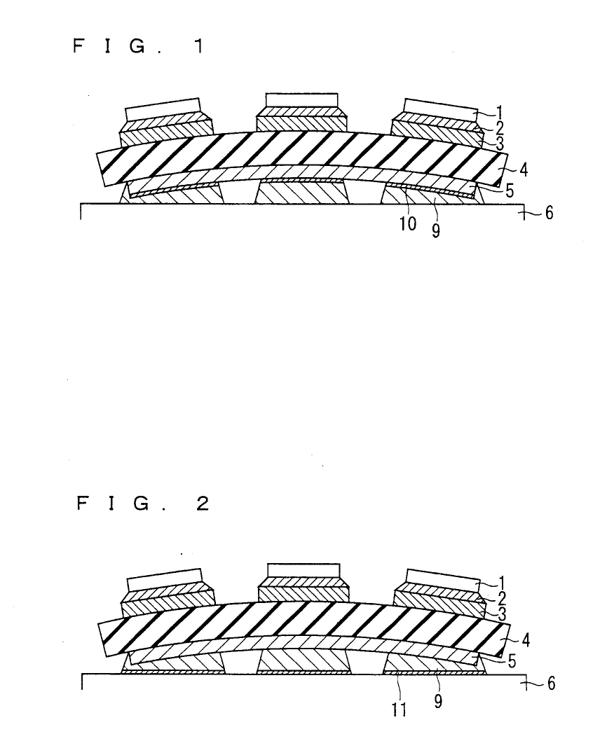

FIG. 1 shows the structure of a semiconductor module according to a first preferred embodiment. As shown in FIG. 1, semiconductor chips 1 are disposed on metals 3 through solder layers 2, and the plurality of metals 3 are formed on an insulating substrate 4 so as to be apart from each other.

A metal 5 is formed over an entire back surface of the insulating substrate 4, and the insulating substrate 4 is disposed on a base plate 6 through metal platings 10 as first metal platings and solder layers 9.

The metal platings 10 and the solder layers 9 are selectively formed in corresponding regions directly below the regions in which the semiconductor chips 1 are disposed, and are apart from each other.

With the above-mentioned structure, even when the insulating substrate 4 warps due to, for example, thermal expansion as shown in FIG. 1, solder voids are prevented from occurring because the solder layers 9 are separated from each other. Accordingly, the assemblability of the semiconductor module can be kept excellent.

Note that a wide bandgap semiconductor of SiC or the like can be used for the semiconductor chips 1.

(A-2. Manufacturing Method)

Next, a method of manufacturing the semiconductor module is described. First, the insulating substrate 4 is prepared, and the metals 3 are formed selectively on the surface thereof. Then, the metal 5 is formed on the back surface of the insulating substrate 4.

Next, the metal platings 10 having high solder wettability are formed in regions corresponding to the regions directly below the semiconductor chips 1. The solder layers 9 are respectively formed on the metal platings 10, and then are brought into contact with the base plate 6 to be connected thereto.

Further, the solder layers 2 are formed on the respective metals 3, and the corresponding semiconductor chips 1 are respectively disposed. The plurality of semiconductor chips 1 are disposed so as to be apart from each other.

(A-3. Effects)

According to the first preferred embodiment of the present invention, the semiconductor module includes: the insulating substrate 4; a plurality of semiconductor chips 1 disposed so as to be apart from each other on the surface of the insulating substrate 4; the solder layers 9 formed, on the back surface side of the insulating substrate 4, only at positions corresponding to positions at which the respective semiconductor chips 1 are disposed; and the base plate 6 connected to the insulating substrate 4 through the solder layers 9. Accordingly, it is possible to prevent soldered regions on the back surface of the insulating substrate 4 from increasing while ensuring a heat dissipation path, prevent the generation of the solder voids 8, and keep excellent assemblability. Further, the solder regions reduce, and accordingly the semiconductor chips 1 can be disposed and the semiconductor module can shrink.

Further, according to the first preferred embodiment of the present invention, the semiconductor module further includes the metal platings 10 as the first metal platings that are formed only at the positions corresponding to the positions at which the respective semiconductor chips 1 are disposed on the back surface of the insulating substrate 4, in which the solder layers 9 are formed on the metal platings 10. Accordingly, it is possible to prevent the generation of the solder voids 8 and keep excellent assemlability.

Further, according to the first preferred embodiment of the present invention, a method of manufacturing a semiconductor module includes the steps of: (a) preparing the insulating substrate 4; (b) disposing a plurality of semiconductor chips 1 on the surface of the insulating substrate 4 so as to be apart from each other; (c) forming the solder layers 9 only at positions corresponding to positions at which the respective semiconductor chips 1 are disposed on the back surface side of the insulating substrate 4; and (d) connecting the insulating substrate 4 to the base plate 6 through the solder layers 9. Accordingly, it is possible to prevent the generation of the solder voids 8 and keep excellent assemblability.

Further, according to the first preferred embodiment of the present invention, the method of manufacturing a semiconductor module further includes the step of (e) forming, prior to the step (c), the metal platings 10 as the first metal platings at only the positions corresponding to the positions at which the respective semiconductor chips 1 are disposed on the back surface of the insulating substrate 4, in which the solder layers 9 are formed on the metal platings 10 in the step (c). Accordingly, it is possible to prevent the generation of the solder voids 8 and keep excellent assemblability.

### B. Second Preferred Embodiment

(B-1. Configuration)

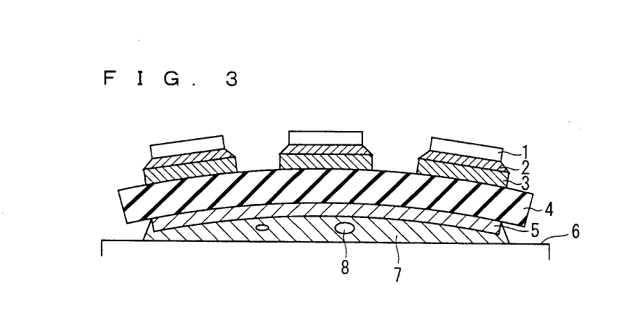

FIG. 2 shows the structure of a semiconductor module according to a second preferred embodiment. As shown in FIG. 2, the semiconductor chips 1 are disposed on the metals 3 through the solder layers 2, and the plurality of metals 3 are formed on the insulating substrate 4 so as to be apart from each other.

The metal 5 is formed over an entire back surface of the insulating substrate 4, and the insulating substrate 4 is disposed on the base plate 6 through metal platings 11 as the second metal platings and the solder layers 9.

The metal platings 11 and the solder layers 9 are selectively formed only in the regions directly below the regions in which the semiconductor chips 1 are disposed so as to be apart from each other.

With the above-mentioned configuration, as shown in FIG. 1, the solder voids are prevented from occurring in the solder layers 9 even when the insulating substrate 4 warps due to thermal expansion or the like, whereby it is possible to keep excellent assemblability of the semiconductor module.

Note that the second preferred embodiment may be combined with the first preferred embodiment. That is, the metal platings 10 of FIG. 1 may also be provided in the structure of FIG. 2.

(B-2. Manufacturing Method)

Next, a method of manufacturing the semiconductor module is described.

First, the insulating substrate 4 is prepared, and the metals 3 are formed selectively on the surface thereof. Then, the metal 5 is formed on the back surface of the insulating substrate 4.

Next, the metal platings 11 having high solder wettability are formed in the regions corresponding to the regions directly below the semiconductor chips 1 described below on the base plate 6. The solder layers 9 are respectively formed on the metal platings 11, and then are brought into contact with the insulating substrate 4 to be connected thereto.

Further, the solder layers 2 are formed on the respective metals 3, and the corresponding semiconductor chips 1 are respectively disposed. The plurality of semiconductor chips 1 are disposed so as to be apart from each other.

(B-3. Effects)

According to the second preferred embodiment of the present invention, the semiconductor module further includes the metal platings 11 as the second metal platings that are formed only at positions corresponding to the positions at which the respective semiconductor chips 1 are disposed on the base plate 6, in which the solder layers 9 are formed on the metal platings 11. Accordingly, it is possible to prevent the generation of the solder voids 8 and keep excellent assemblability.

Further, according to the second preferred embodiment of the present invention, the method of manufacturing a semiconductor module further includes the steps of (f) forming, prior to the step (c), the metal platings 11 as the second metal platings only at positions corresponding to the positions at which the respective semiconductor chips 1 are disposed on the base plate 6, in which the solder layers 9 are formed on the metal platings 11 in the step (c). Accordingly, it is possible to prevent the generation of the solder voids 8 and keep excellent assemblability.

While the invention has been shown and described in detail, the foregoing description is in all aspects illustrative and not restrictive. It is therefore understood that numerous modifications and variations can be devised without departing from the scope of the invention.

What is claimed is:

1. A semiconductor module, comprising:
an insulating substrate;
a plurality of semiconductor chips disposed on a surface of said insulating substrate so as to be apart from each other;
solder layers formed, on a back surface side of said insulating substrate, only at positions corresponding to positions at which said respective semiconductor chips are disposed; and
a base plate connected to said insulating substrate through said solder layers.

2. The semiconductor module according to claim 1, further comprising first metal platings formed, on the bask surface of said insulating substrate, only at positions corresponding to the positions at which said respective semiconductor chips are disposed,
wherein said solder layers are formed on said first metal platings.

3. The semiconductor module according to claim 1, further comprising second metal platings formed only at positions on said base plate corresponding to the positions at which said respective semiconductor chips are disposed,
wherein said solder layers are formed on said second metal platings.

4. The semiconductor module according to claim 1, wherein said respective semiconductor chips are SiC semiconductor chips.

5. A method of manufacturing a semiconductor module, comprising the steps of:
(a) preparing an insulating substrate;
(b) disposing a plurality of semiconductor chips on a surface of said insulating substrate so as to be apart from each other;
(c) forming solder layers only at positions corresponding to positions at which said respective semiconductor chips are disposed, on a back surface side of said insulating substrate; and
(d) connecting said insulating substrate to said base plate through said solder layers.

6. The method of manufacturing a semiconductor module according to claim 5, further comprising the step of (e) forming, prior to said step (c), first metal platings only at positions corresponding to the positions at which said respective semiconductor chips are disposed on the back surface of said insulating substrate,
wherein said solder layers are formed on said first metal platings in said step (c).

7. The method of manufacturing a semiconductor module according to claim 5, further comprising the step of (f) forming, prior to said step (c), second metal platings only at positions corresponding to the positions at which said respective semiconductor chips are disposed on said base plate,
wherein said solder layers are formed on said second metal platings in said step (c).

8. The method of manufacturing a semiconductor module according to claim 5, wherein in said step (b), the plurality of SiC semiconductor chips are disposed on the surface of said insulating substrate so as to be apart from each other.
